(19) United States
(12) Patent Application Publication
(10) Pub. No.: US 2014/0268978 A1
(43) Pub. Date: Sep. 18, 2014

(54) SEMICONDUCTOR MEMORY DEVICE HAVING ASYMMETRIC ACCESS TIME

(71) Applicant: SAMSUNG ELECTRONICS CO., LTD., Suwon-si (KR)

(72) Inventors: Hyo-Jin CHOI, Suwon-si (KR); Su-A KIM, Seongnam-si (KR); Young-Hoon SON, Suwon-si (KR); Jung-Ho AHN, Seoul (KR); Hak-Soo YU, Seongnam-si (KR); Jae-Youn YOUN, Seoul (KR)

(73) Assignees: SAMSUNG ELECTRONICS CO., LTD., Suwon-si (KR); SNU R&DB FOUNDATION, Seoul (KR)

(21) Appl. No.: 14/144,470

(22) Filed: Dec. 30, 2013

(30) Foreign Application Priority Data
Mar. 15, 2013 (KR) 10-2013-0028077

(51) Int. Cl. G11C 5/06

(52) U.S. Cl. CPC G11C 5/063
USPC 365/63

(57) ABSTRACT

A semiconductor memory device may include a plurality of data input/output DQ pads and a plurality of first and second memory cell arrays. Each path of a first set of data paths from each of the plurality of first memory cell arrays to a corresponding DQ pad is physically shorter than each path of a second set of data paths from each of the plurality of second memory cell arrays to the corresponding DQ pad. Each of the plurality of first memory cell arrays is a designated first-speed access cell array and each of the plurality of second memory cell arrays is a designated second-speed access cell array, the second-speed being slower than the first-speed. A size of the each of the plurality of first memory cell arrays is smaller than a size of the each of the plurality of second memory cell arrays.

### CROSS-REFERENCE TO RELATED APPLICATION

This application claims priority under 35 USC §119 to Korean Patent Application No. 10-2013-0028077, filed on Mar. 15, 2013, in the Korean Intellectual Property Office (KIPO), the contents of which are herein incorporated by reference in its entirety.

### BACKGROUND

In general, a Dynamic Random Access Memory (DRAM) may be designed in a symmetrical structure in order to have the same access time in all address regions.

A memory cell array may be constructed in a bank structure, in which each bank includes a plurality of sub-arrays. Data stored in each cell are transferred to an input/output pad through a path having a hierarchical structure, for example, bit line sense amplifier—local input/output path—input/output amplifier—global input/output path—input/output buffer. Thus, in order to minimize difference in access delay time depending on the distance from cells to the input/output pad, the cell array is generally disposed in a symmetrical structure.

Nevertheless, since a plurality of cells are disposed on a two-dimensional plane, the difference in access delay time always tends to exist depending on the distance from each cell to an input/output pad.

Therefore, the longest access time is determined as an access time of a DRAM in order to ensure the exact operation.

### SUMMARY

Some example embodiments provide a semiconductor memory device having an asymmetric access time, in which access times are different from each other according to alignment spaces by actively utilizing differences between access times of each cell.

Further, some example embodiments provide a semiconductor memory device having an asymmetric access time, which includes a cell array region having a high-speed access time and a cell array region having a low-speed access time.

In addition, some example embodiments provide a semiconductor memory device having an asymmetric access time, which includes a cell array region having a high-speed access time and a cell array region having a low-speed access time according to a physical distance with respect to a TSV (Through Silicon Via).

According to example embodiments, a semiconductor memory device includes a plurality of data input/output DQ pads and a plurality of first and second memory cell arrays. The plurality of data input/output DQ pads are disposed on a semiconductor substrate. The plurality of first and second memory cell arrays are disposed on the semiconductor substrate. Each path of a first set of data paths from each of the plurality of first memory cell arrays to a corresponding DQ pad is physically shorter than each path of a second set of data paths from each of the plurality of second memory cell arrays to the corresponding DQ pad. Each of the plurality of first memory cell arrays may be a designated high-speed access cell array and each of the plurality of second memory cell arrays may be a designated low-speed access cell array. A size of the each of the plurality of first memory cell arrays may be less than a size of the each of the plurality of second memory cell arrays.

In example embodiments, the memory cell arrays may include first memory cell arrays disposed in a region adjacent to a region of the plurality of DQ pads to have a first data path length and operated at a first access time, and second memory cell arrays disposed in a region away from the region of the plurality of DQ pads to have a second data path length longer than the first data path length and operated at a second access time longer than the first access time.

A plurality of pads including a plurality of command/address (CMD/ADDR) pads and a plurality of DQ pads may be disposed along one of a horizontal central line and a vertical central line of the semiconductor substrate.

The plurality of DQ pads may be disposed at a center and the a plurality of CMD/ADDR pads are disposed at left and right sides of the output pads.

The plurality of DQ pads may be disposed at a center of the vertical central line and the plurality of CMD/ADDR pads are disposed along the horizontal central line.

The plurality of DQ pads may be disposed along one of left and right vertical edge lines, and the plurality of CMD/ADDR pads are disposed along a remaining one of the left and right vertical edge lines.

The plurality of DQ pads may be disposed along one of left and right vertical edge lines, and the plurality of CMD/ADDR pads are disposed along the vertical central line.

The plurality of DQ pads may be disposed along one of left and right vertical edge lines, and the plurality of CMD/ADDR pads are disposed along one of upper and lower horizontal edge lines.

The first memory cell array and the second memory cell array adjacent to each other may share an input/output sense amplifier circuit.

The first memory cell array and the second memory cell array adjacent to each other may have individual input/output sense amplifier circuits, respectively.

According to example embodiments, a semiconductor memory device includes a logic layer, first and second memory layers and a vertical connection member. The first memory layer is located above the logic layer. The first memory layer includes a plurality of first and second memory cell arrays and a first set of DQ pads disposed on a substrate of the first memory layer. The second memory layer is located above the first memory layer. The second memory layer includes a plurality of third and fourth memory cell arrays and a second set of DQ pads disposed on a substrate of the second memory layer. The vertical connection member electrically connects the logic layer, the first memory layer, the second memory layer to each other. The vertical connection member is a data path between the logic layer and each of the first and second memory layers. For the first memory layer, a shortest data path from one of the plurality of first memory cell arrays to a first DQ pad of the first set of DQ pads is physically shorter than a shortest data path from one of the plurality of second memory cell arrays to the first DQ pad. For the second memory layer, a shortest data path from one of the plurality of third memory cell arrays to a second DQ pad of the second set of DQ pads is physically shorter than a shortest data path from one of the plurality of fourth memory cell arrays to the second DQ. Each of the plurality of first and third memory cell arrays is a designated high-speed access cell array and each of the plurality of second and fourth memory cell arrays is a designated low-speed access cell array.

In example embodiments, each of the first and second memory layers may include a plurality of memory cell arrays disposed on a semiconductor substrate and a plurality of input/output pads disposed on the semiconductor substrate and electrically connected to the vertical connection member. Access times of the memory cell arrays may be different from each other in proportion to lengths of data paths between the vertical connection member and the memory cell arrays.

The logic layer may include a memory controller, and access times of the memory cell arrays included in the memory layers may be different from each other in proportion to lengths of data paths between the memory controller and the memory cell arrays.

According to example embodiments, a semiconductor memory device includes a substrate, a first set of memory cell arrays, a second set of memory cell arrays and a plurality of pads. The substrate extends a first direction and a second direction perpendicular to the first direction. The first set of memory cell arrays is disposed on the substrate and is designated as a high-speed access cell array. The second set of memory cell arrays is disposed on the substrate and is designated as a low-speed access cell array. The plurality of pads are disposed on the substrate and include a plurality of DQ pads and a plurality of ADDR/CMD pads. The plurality of DQ pads are disposed along the first direction of the substrate. For each memory cell array of the first set of memory cell arrays, a shortest data path from the memory cell array to a corresponding DQ pad is physically shorter than any shortest data path from anyone of the second set of memory cell arrays to the corresponding DQ pad.

### BRIEF DESCRIPTION OF THE DRAWINGS

Illustrative, non-limiting example embodiments will be more clearly understood from the following detailed description taken in conjunction with the accompanying drawings.

FIG. 1 is a concept view illustrating a high-speed access cell and a low-speed access cell of a semiconductor memory device having an asymmetric access time according to an example embodiment.

FIG. 2 is a view illustrating a layout of a semiconductor memory chip 100 of a first example embodiment, in which an IOSA is shared and a plurality of pads are disposed at a horizontal center of the semiconductor memory chip 100.

FIG. 3 is a view illustrating a layout of a first modified example in which IOSAs for the high-speed and the low-speed of the first example embodiment of FIG. 2 are separated from each other.

FIG. 4 is a view illustrating a layout of a second modified example in which IOSAs of all of the cell arrays of the first example embodiment of FIG. 2 are separated from each other.

FIG. 5 is a view illustrating a layout of a semiconductor memory chip 200 of a second example embodiment, in which a plurality of pads are disposed at a vertical center of the semiconductor memory chip 200 and an IOSA is shared.

FIG. 6 is a view illustrating a layout of a first modified example in which IOSAs for the high-speed cell array and the low-speed cell array of the second example embodiment of FIG. 5 are separated.

FIG. 7 is a view illustrating a layout of a second modified example in which IOSAs of all of the cell arrays of the second example embodiment of FIG. 5 are separated.

FIG. 8 is a view illustrating a layout of a third modified example in which DQ pads of the second example embodiment of FIG. 5 are disposed at a center.

FIG. 9 is a view illustrating a layout of a semiconductor memory chip 300 of a third example embodiment, in which command and address CMD/ADDR pads are disposed at a horizontal center of the semiconductor memory chip 300 and data input/output DQ pads are disposed at a vertical center of the semiconductor memory chip 300.

FIG. 10 is a view illustrating a layout of a first modified example in which IOSAs for the high-speed cell array and the low-speed cell array of the third example embodiment of FIG. 9 are separated from each other.

FIG. 11 is a view illustrating a layout of a second modified example in which IOSAs of all of the cell arrays of the third example embodiment of FIG. 9 are separated from each other.

FIG. 12 is a view illustrating a layout of a semiconductor memory chip 400 of a fourth example embodiment, in which command and address CMD/ADDR pads are vertically disposed at a right edge of the semiconductor memory chip 400 and data input/output DQ pads are vertically disposed at a left edge of the semiconductor memory chip 400.

FIG. 13 is a view illustrating a layout of a first modified example in which IOSAs for the high-speed cell array and the low-speed cell array of the fourth example embodiment of FIG. 12 are separated from each other.

FIG. 14 is a view illustrating a layout of a second modified example in which IOSAs of all of the cell arrays of the fourth example embodiment of FIG. 12 are separated from each other.

FIG. 15 is a view illustrating a layout of a semiconductor memory chip 500 of a fifth example embodiment, in which command and address CMD/ADDR pads are disposed at a vertical center of the semiconductor memory chip 500 and data input/output DQ pads are vertically disposed at a left edge of the semiconductor memory chip 500.

FIG. 16 is a view illustrating a layout of a first modified example in which IOSAs of all of the cell arrays of the fifth example embodiment of FIG. 15 are separated from each other.

FIG. 17 is a view illustrating a layout of a semiconductor memory chip 600 of a sixth example embodiment, in which command and address CMD/ADDR pads are disposed at a horizontal edge of the semiconductor memory chip 600 and data input/output DQ pads are disposed at a vertical edge of the semiconductor memory chip 600.

FIG. 18 is a view illustrating a layout of a first modified example in which IOSAs of the high-speed cell array and the low-speed cell array of the sixth example embodiment of FIG. 17 are separated from each other.

FIG. 19 is a view illustrating a layout of a second modified example in which IOSAs of all of the cell arrays of the sixth example embodiment of FIG. 17 are separated from each other.

FIG. 20 is a view illustrating a stack type semiconductor memory chip 700 using a TSV (Through Silicon Via) according to the seventh example embodiment.

FIG. 21 is a view illustrating a layout of a first modified example in which a high-speed cell array and a low-speed cell array are constructed on each memory layer of the seventh example embodiment of FIG. 20.

FIG. 22 is a view illustrating a layout of a second modified example in which a high-speed cell array and a low-speed cell array are constructed on each memory layer of the seventh example embodiment of FIG. 20.

FIG. 23 is a block diagram illustrating a configuration of a DRAM device 800 according to an example embodiment.

FIG. 24 is a block diagram illustrating an electronic system including a semiconductor memory device according to an example embodiment.

FIG. 25 is a block diagram illustrating a computer system including a semiconductor memory device according to an example embodiment

### DETAILED DESCRIPTION OF THE EMBODIMENTS

Various example embodiments will be described more fully with reference to the accompanying drawings, in which some example embodiments are shown. The present disclosure may, however, be embodied in many different forms and should not be construed as limited to the embodiments set forth herein. Like reference numerals refer to like elements throughout the accompanying drawings.

It will be understood that, although the terms first, second, etc. may be used herein to describe various elements, these elements should not be limited by these terms. Unless indicated otherwise, these terms are used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the disclosure. As used herein, the singular forms “a,” “an” and “the” are intended to include the plural forms as well, unless the context clearly indicates otherwise. It will be further understood that the terms such as “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a concept view illustrating a high-speed access cell and a low-speed access cell of a semiconductor memory device having an asymmetric access time according to an example embodiment.

Referring to FIG. 1, the semiconductor memory device 100 includes a low-speed access cell array 110 placed physically away from a data input/output DQ pad and a high-speed access cell array 120 placed physically near the data input/output DQ pad. A distance between a cell of the low-speed access cell array 110 and the data input/output DQ pad is equal to Ls1 (a length between a pad and an input/output sense amplifier)+Ls2 (a length between a bit-line sense amplifier and a cell). A distance between a cell of the high-speed access cell array 120 and the data input/output DQ pad is equal to Lf1 (a length between a pad and an input/output sense amplifier)+Lf2 (a length between a bit-line sense amplifier and a cell). Thus, difference in the access delay time may exist due to Ls1+Ls2>Lf1+Lf2.

According to an example embodiment, an SFDRAM (Slow-Fast DRAM) having two access times is configured by intentionally dividing cell arrays into a high-speed cell array and a low-speed cell array according to a physical distance with respect to a corresponding DQ pad in one chip.

Hereinafter, example embodiments of the SFDRAM will be described in detail.

### Example Embodiment 1

### A Plurality of Pads Disposed at Horizontal Center

FIG. 2 is a view illustrating a layout of a semiconductor memory chip 100 of a first example embodiment, in which an IOSA is shared and a plurality of pads are disposed at a horizontal center of the semiconductor memory chip 100. The plurality of pads may include, for example, data input/output DQ pads and command/address (CMD/ADDR) pads.

Referring to FIG. 2, a plurality of pads are disposed in two rows at the horizontal center of the chip 100 according to the first example embodiment. For example, the plurality of pads are disposed in parallel with a row decoder RD and perpendicularly to a column decoder CD. In one embodiment, DQ pads of the plurality of pads are disposed at an edge of the chip 100, and CMD and ADDR pads are disposed at the center of the chip 100.

In this structure, cell arrays CA01˜CA04, CA11, CA14, CA21, CA24 and CA31˜CA34 disposed at the edge of the chip 100 are placed relatively far away from the DQ pads along a DQ data path. Thus, these cell arrays may be a designated low-speed cell array 110. The cell array CA12, CA13, CA22 and CA23 disposed in the center of the chip 100 are placed at a position relatively closed to the DQ pads along the DQ data path. Thus, these cell arrays may be a designated high-speed access cell array 120.

As shown, the distance Ls1 (designated as an arrow dot line in drawings) from the center C of the chip 100 to an IOSA of the cell array CA01 is longer than the distance Lf1 (designated as an arrow full line in drawings) from the center C to an IOSA of the cell array CA23. Thus, since a difference in access delay time exists due to the distance difference, cell data of the cell array CA23 are accessed at a higher speed than cell data of the cell array CA01.

However, the difference in access time may not exist between the cell array CA23 and the cell array CA24 because the cell array CA24 shares the IOSA with the cell array CA23.

In one embodiment, a physical size of the high-speed cell array CA23 is smaller than a physical size of the low-speed cell array CA01 as shown in FIG. 2.

FIG. 3 is a view illustrating a layout of a first modified example in which IOSAs for the high-speed cell array and the low-speed cell array of the first example embodiment of FIG. 2 are separated from each other. In the following description, the same elements as those of FIG. 2 will be assigned with the same reference numerals, and the detailed description will be omitted.

Referring to FIG. 3, in the first modified example, the cell arrays CA23 and CA24 do not share one IOSA, but have individual IOSAs, respectively.

Therefore, a distance Ls1 (designated as an arrow dot line of FIG. 3) from an IOSA of the cell array CA24 to the center C of the chip 100 is longer than a distance Lf1 (designated as an arrow full line of FIG. 3) from the center C to an IOSA of the cell array CA23. Thus, since a difference in access delay time exists due to the distance difference, cell data of the cell array CA23 are accessed at a higher speed than cell data of the cell array CA24.

FIG. 4 is a view illustrating a layout of a second modified example in which IOSAs of all of the cell arrays of the first example embodiment of FIG. 2 are separated. In the following description, the same elements as those of FIG. 3 will be assigned with the same reference numerals, and the detailed description will be omitted.

Referring to FIG. 4, differently from the first modified example, the low-speed cell arrays of the second modified example, for example, the cell arrays CA01 and CA02 do not share one IOSA, but have individual IOSAs, respectively.

### Example Embodiment 2

### A Plurality of Pads Disposed at Vertical Center

FIG. 5 is a view illustrating a layout of a semiconductor memory chip 200 of a second example embodiment, in which a plurality of pads are disposed at a vertical center of the semiconductor memory chip 200 and an IOSA is shared. The plurality of pads may include, for example, data input/output DQ pads and command/address (CMD/ADDR) pads.

Referring to FIG. 5, a plurality of pads are disposed in two columns at the horizontal center of the chip 200 according to the second example embodiment. For example, the plurality of pads are disposed in parallel with a column decoder CD and perpendicularly to a row decoder RD. DQ pads of the plurality of pads are disposed at an edge of the chip 200, and CMD and ADDR pads of the plurality of pads are disposed at the center of the chip 200.

In this structure, cell arrays CA01˜CA04, CA11, CA14, CA21, CA24 and CA31˜CA34 disposed at the edge of the chip 200 are placed relatively far away from the DQ pads along a DQ data path. Thus, these cell arrays may be a designated low-speed cell array 210. The cell array CA12, CA13, CA22 and CA23 disposed in the center of the chip 200 are placed at a position relatively closed to the DQ pads along the DQ data path. Thus, each of these cell arrays may be a designated high-speed access cell array 220.

Therefore, the distance Ls1 (designated as an arrow dot line of FIG. 5) from the center C of the chip 200 to an IOSA of the cell array CA01 is longer than the distance Lf1 (designated as an arrow full line of FIG. 5) from the center C to an IOSA of the cell array CA23. Thus, since a difference in access delay time exists due to the distance difference, cell data of the cell array CA23 are accessed at a speed higher than cell data of the cell array CA01.

However, the difference in access time may not exist between the cell array CA23 and the cell array CA24, which shares an IOSA with the cell array CA23.

In one embodiment, a physical size of the high-speed cell array CA23 is smaller than a physical size of the low-speed cell array CA01 as shown in FIG. 2.

FIG. 6 is a view illustrating a layout of a first modified example in which IOSAs for the high-speed cell array and the low-speed cell array of the second example embodiment of FIG. 5 are separated. In the following description, the same elements as those of FIG. 5 will be assigned with the same reference numerals, and the detailed description will be omitted.

Referring to FIG. 6, in the first modified example, the cell arrays CA23 and CA24 do not share one IOSA, but have individual IOSAs, respectively.

Therefore, a distance Ls1 (designated as an arrow dot line of FIG. 6) from an IOSA of the cell array CA24 to the center C of the chip 200 is longer than a distance Lf1 (designated as an arrow full line of FIG. 6) from the center C to an IOSA of the cell array CA23. Thus, since a difference in access delay time exists due to the distance difference, cell data of the cell array CA23 are accessed at a higher speed than cell data of the cell array CA24.

FIG. 7 is a view illustrating a layout of a second modified example in which IOSAs of all of the cell arrays of the second example embodiment of FIG. 5 are separated. In the following description, the same elements as those of FIG. 5 will be assigned with the same reference numerals, and the detailed description will be omitted.

Referring to FIG. 7, differently from the first modified example, the low-speed cell arrays of the second modified example, for example, the cell arrays CA01 and CA02 do not share one IOSA, but have individual IOSAs, respectively.

FIG. 8 is a view illustrating a layout of a third modified example in which DQ pads of the plurality of pads of the second example embodiment of FIG. 5 are disposed at a center. In the following description, the same elements as those of FIG. 5 will be assigned with the same reference numerals, and the detailed description will be omitted.

Referring to FIG. 8, differently from the DQ pads of FIG. 5 which are disposed at an edge, the DQ pads of the third modified example are disposed at a center so that the distance with respect to the high-speed cell arrays 220 disposed at the center may be more reduced.

### Example Embodiment 3

### A Plurality of Pads Disposed in a Cross Shape

FIG. 9 is a view illustrating a layout of a semiconductor memory chip 300 of a third example embodiment, in which command and address CMD/ADDR pads are disposed at a horizontal center of the semiconductor memory chip 300 and data input/output DQ pads are disposed at a vertical center of the semiconductor memory chip 300.

Referring to FIG. 9, the command and address CMD/ADDR pads are disposed in a single row at the horizontal center and the data input/output DQ pads are disposed in two columns at the vertical center of the chip 300 according to the third example embodiment. For example, the command and address CMD/ADDR pads are disposed in parallel with a row decoder RD and the data input/output DQ pads are disposed in parallel with a column decoder CD.

In this structure, cell arrays CA01˜CA04, CA11, CA14, CA21, CA24 and CA31˜CA34 disposed at the edge of the chip 300 are placed relatively far away from the DQ pads along a DQ data path. Thus, each of these cell arrays may be a designated low-speed cell array 310. The cell array CA12, CA13, CA22 and CA23 disposed in the center of the chip 300 are placed at a position relatively closed to the DQ pads along the DQ data path. Thus, each of these cell arrays may be a designated high-speed access cell array 320.

Therefore, the distance Ls1 (designated as an arrow dot line of the drawings) from the center C of the chip 200 to an IOSA of the cell array CA01 is longer than the distance Lf1 (designated as an arrow full line of the drawings) from the center C to an IOSA of the cell array CA23. Thus, since a difference in access delay time exists due to the distance difference, cell data of the cell array CA23 are accessed at a speed higher than cell data of the cell array CA01.

In one embodiment, a physical size of the high-speed cell array CA23 is smaller than a physical size of the low-speed cell array CA01 as shown in FIG. 9.

FIG. 10 is a view illustrating a layout of a first modified example in which IOSAs for the high-speed cell array and the low-speed cell array of the third example embodiment of FIG. 9 are separated from each other. In the following description, the same elements as those of FIG. 9 will be assigned with the same reference numerals, and the detailed description will be omitted.

Referring to FIG. 10, in the first modified example, the cell array CA23 which is a high-speed array and the cell array CA24 which is a low-speed cell array do not share one IOSA, but have individual IOSAs.

Therefore, a distance Ls1 (designated as an arrow dot line of FIG. 10) from an IOSA of the cell array CA24 to the center C of the chip 300 is longer than a distance Lf1 (designated as an arrow full line of FIG. 10) from the center C to an IOSA of the cell array CA23. Thus, since a difference in access delay time exists due to the distance difference, cell data of the cell array CA23 are accessed at a higher speed than cell data of the cell array CA24.

FIG. 11 is a view illustrating a layout of a second modified example in which IOSAs of all of the cell arrays of the third example embodiment of FIG. 9 are separated from each other. In the following description, the same elements as those of FIG. 9 will be assigned with the same reference numerals, and the detailed description will be omitted.

Referring to FIG. 11, differently from the first modified example, the low-speed cell arrays of the second modified example, for example, the cell arrays CA01 and CA02 do not share one IOSA, but have individual IOSAs, respectively.

### Example Embodiment 4

### A Plurality of Pads Disposed in a II-Shape at Edge

FIG. 12 is a view illustrating a layout of a semiconductor memory chip 400 of a fourth example embodiment, in which command and address CMD/ADDR pads are vertically disposed at a right edge of the semiconductor memory chip 400 and data input/output DQ pads are vertically disposed at a left edge of the semiconductor memory chip 400.

Referring to FIG. 12, the data input/output DQ pads are vertically disposed in a single column at the left edge of the semiconductor memory chip 400 and the command and address CMD/ADDR pads are vertically disposed in a single column at the right edge of the semiconductor memory chip 400 according to the third example embodiment. For example, the plurality of pads are disposed to be perpendicular to a row decoder RD and in parallel with a column decoder CD.

In this structure, cell arrays CA11, CA12, CA21 and CA22 disposed at a center near the left edge of the chip 400 are placed at a position relatively close to the DQ pads along a DQ data path. Thus, each of these cell arrays may be a designated high-speed cell array 420. The other cell arrays CA01˜CA04, CA13, CA14, CA23, CA24 and CA31˜CA34 of the chip 400 are placed relatively far away from the DQ pads along the DQ data path. Thus, each of these cell arrays may be a designated low-speed access cell array 410.

The distance Ls1 (designated as an arrow dot line of the drawings) from the left edge of the chip 400 to an IOSA of the cell array CA03 is longer than the distance Lf1 (designated as an arrow full line of the drawings) from the left edge to an IOSA of the cell array CA21. Thus, since difference in access delay time exists due to the distance difference, cell data of the cell array CA21 are accessed at a speed higher than cell data of the cell array CA03.

In one embodiment, a physical size of the high-speed cell array CA21 is smaller than a physical size of the low-speed cell array CA03 as shown in FIG. 12.

FIG. 13 is a view illustrating a layout of a first modified example in which IOSAs for the high-speed cell array and the low-speed cell array of the fourth example embodiment of FIG. 12 are separated from each other. In the following description, the same elements as those of FIG. 12 will be assigned with the same reference numerals, and the detailed description will be omitted.

Referring to FIG. 13, in the first modified example, the cell arrays CA01, CA11, CA21 and CA31, which are arranged at a left edge, constitute a high-speed cell array 420 and have individual IOSAs without sharing an IOSA with the cell arrays CA02, CA12, CA22 and CA32 of a low-speed cell array 410.

Therefore, a distance Ls1 (designated as an arrow dot line of FIG. 13) from the left edge of the chip 400 to an IOSA of the cell array CA03 is longer than a distance Lf1 (designated as an arrow full line of FIG. 13) from the left edge to an IOSA of the cell array CA21. Thus, since a difference in access delay time exists due to the distance difference, cell data of the cell array CA21 are accessed at a speed higher than cell data of the cell array CA03.

FIG. 14 is a view illustrating a layout of a second modified example in which IOSAs of all of the cell arrays of the fourth example embodiment of FIG. 12 are separated from each other. In the following description, the same elements as those of FIG. 12 will be assigned with the same reference numerals, and the detailed description will be omitted.

Referring to FIG. 14, differently from the first modified example, the low-speed cell arrays of the second modified example, for example, the cell arrays CA03 and CA04 do not share one IOSA, but have individual IOSAs, respectively.

### Example Embodiment 5

### Data Input/Output Pads Disposed at Edge/Command/Address Pads Disposed at Vertical Center

FIG. 15 is a view illustrating a layout of a semiconductor memory chip 500 of a fifth example embodiment, in which command and address CMD/ADDR pads are disposed at a vertical center and data input/output DQ pads are vertically disposed at a left edge.

Referring to FIG. 15, the data input/output pads DQ of a single row are vertically disposed at the left edge, and the command and address CMD/ADDR pads of a single row are disposed at the vertical center of the chip 500 according to the fifth example embodiment. That is, the input/output pads are disposed perpendicularly to a row decoder RD and in parallel with a column decoder CD.

In this structure, cell arrays CA01, CA11, CA21 and CA31 disposed near the left edge of the chip 500 are placed at a position relatively closed to the DQ pads along a DQ data path. Thus, these cell arrays may be a designated high-speed cell array 520. The other cell arrays CA02˜CA04, CA12˜CA14, CA22˜CA24 and CA32˜CA34 of the chip 500 are placed relatively far away from the DQ pads along the DQ data path. Thus, these cell arrays may be a designated low-speed access cell arrays 510. In one embodiment, the command and address CMD/ADDR pads are not disposed at the vertical center but disposed on a vertical separation line about which the high-speed cell array 520 and the low-speed cell array 510 are separated from each other. The high-speed arrays CA01, CA11, CA21 and CA31 and the low-speed cell arrays CA02, CA12 and CA22, CA32 do not share one IOSA, but have individual IOSAs, respectively.

Therefore, the distance Ls1 (designated as an arrow dot line of the drawings) from the left edge of the chip 500 to an IOSA of the cell array CA03 is longer than the distance Lf1 (designated as an arrow full line of the drawings) from the left edge to an IOSA of the cell array CA21. Thus, since a difference in access delay time exists due to the distance difference, cell data of the cell array CA21 are accessed at a speed higher than cell data of the cell array CA03.

In one embodiment, a physical size of the high-speed cell array CA21 is smaller than a physical size of the low-speed cell array CA03 as shown in FIG. 15.

FIG. 16 is a view illustrating a layout of a first modified example in which IOSAs of all of the cell arrays of the fifth example embodiment of FIG. 15 are separated from each other. In the following description, the same elements as those of FIG. 15 will be assigned with the same reference numerals, and the detailed description will be omitted.

Referring to FIG. 16, differently from the fifth example embodiment, the low-speed cell arrays of the first modified example, for example, the cell arrays CA03 and CA04 do not share one IOSA, but have individual IOSAs, respectively.

### Example Embodiment 6

### Disposition in L-Shape at Edge

FIG. 17 is a view illustrating a layout of a semiconductor memory chip 600 of a sixth example embodiment, in which command and address CMD/ADDR pads are disposed at a horizontal edge of the semiconductor memory chip 600 and data input/output DQ pads are disposed at a vertical edge of the semiconductor memory chip 600.

Referring to FIG. 17, the data input/output pads DQ of a single row are vertically disposed at the left edge and the command and address CMD/ADDR pads of a single column are horizontally disposed at the upper horizontal edge of the chip 600 according to the sixth example embodiment. That is, the input/output pads are disposed in parallel with a column decoder CD and the command and address CMD/ADDR pads are disposed in parallel with a row decoder RD.

In this structure, cell arrays CA01, CA02, CA11 and CA12 disposed near the left edge of the chip 600 are placed at a position relatively closed to the DQ pads along a DQ data path and relatively closed to the command and address CMD/ADDR pads. Thus, these cell arrays may be a designated high-speed cell array 620. The other cell arrays CA03, CA04, CA13, CA14, CA21˜CA24 and CA31˜CA34 of the chip 600 are placed relatively far away from the DQ pads and the command and address CMD/ADDR pads along the DQ data path. Thus, these cell arrays may be a designated low-speed access cell array 610. The cell arrays CA01, CA11, CA21 and CA31 of the high-speed cell array 620 do not share one IOSA with cell arrays CA02, CA12, CA22 and CA32 of the low-speed cell array 410, but share the IOSA with each other.

Therefore, a distance Ls1 (designated as an arrow dot line of FIG. 13) from the left edge of the chip 600 to an IOSA of the cell array CA03 is longer than a distance Lf1 (designated as an arrow full line of FIG. 13) from the left edge to an IOSA of the cell array CA11. Thus, since a difference in access delay time exists due to the distance difference, cell data of the cell array CA11 are accessed at a speed higher than cell data of the cell array CA03.

In one embodiment, a physical size of the high-speed cell array CA11 is smaller than a physical size of the low-speed cell array CA03 as shown in FIG. 17.

FIG. 18 is a view illustrating a layout of a first modified example in which IOSAs of the high-speed cell array and the low-speed cell array of the sixth example embodiment of FIG. 17 are separated from each other. In the following description, the same elements as those of FIG. 17 will be assigned with the same reference numerals, and the detailed description will be omitted.

Referring to FIG. 18, in the first modified example, the cell arrays CA01, CA11, CA21 and CA31 which are arranged at a left edge of the semiconductor memory chip 600 and constitute a high-speed cell array and the cell arrays CA02, CA12, CA22 and CA32 which constitute a low-speed cell array 610 do not share one IOSA, but have individual IOSAs, respectively.

Therefore, a distance Ls1 (designated as an arrow dot line of FIG. 18) from the left edge of the chip 600 to an IOSA of the cell array CA03 is longer than a distance Lf1 (designated as an arrow full line of FIG. 13) from the left edge to an IOSA of the cell array CA21. Thus, since a difference in access delay time exists due to the distance difference, cell data of the cell array CA21 are accessed at a speed higher than cell data of the cell array CA03.

FIG. 19 is a view illustrating a layout of a second modified example in which IOSAs of all of the cell arrays of the sixth example embodiment of FIG. 17 are separated from each other. In the following description, the same elements as those of FIG. 17 will be assigned with the same reference numerals, and the detailed description will be omitted.

Referring to FIG. 19, differently from the first modified example, the low-speed cell arrays of the second modified example, for example, the cell arrays CA03 and CA04 do not share one IOSA, but have individual IOSAs, respectively.

### Example Embodiment 7

### Three Dimensional Disposition

FIG. 20 is a view illustrating a stack type semiconductor memory chip 700 using a TSV (Through Silicon Via) according to the seventh example embodiment.

The stack type semiconductor memory device 700 may include a logic layer 710 and first and second memory layers 720 and 722 above the logic layer 710, which are connected to each other through the TSV 730.

Cell arrays 720a, which are disposed on the memory layer 720 closed to the logic layer 710, have a relatively short data path to DQ pads through the TSV 730. Cell arrays 722a, which are disposed on the memory layer 722 far away from the logic layer 710, has a relatively long data path to DQ pads through the TSV 730. Thus, the cell arrays 720a of the memory layer 720 may be designated high-speed cell arrays and the cell arrays 722a of the memory layer 722 may be designated low-speed cell arrays.

Therefore, the distance Ls1 (designated as an arrow dot line of the drawings) from the logic layer 710 of the stack-type chip 700 to the cell array 722a of the memory layer 722 is longer than the distance Lf1 (designated as an arrow full line of the drawings) from the [left] logic layer 710 to the cell array 720a of the memory layer 720. Thus, since a difference in access delay time exists due to the distance difference, cell data of the cell array 720a are accessed at a speed higher than cell data of the cell array 722a.

FIG. 21 is a view illustrating a layout of a first modified example in which a high-speed cell array and a low-speed cell array are constructed on each memory layer of the seventh example embodiment of FIG. 20. In the following description, the same elements as those of FIG. 20 will be assigned with the same reference numerals, and the detailed description will be omitted.

Referring to FIG. 21, the cell arrays 720a of the memory layer 720, which are near the TSV 730, may be designated high-speed cell arrays and the cell arrays 720b of the memory layer 720, which are far away from the TSV, may be designated low-speed cell arrays. Likewise, the cell arrays 722a of the memory layer 722, which are near the TSV 730, may be designated high-speed cell arrays and the cell arrays 722b of the memory layer 722, which are far away from the TSV 730, may be designated low-speed cell arrays.

Therefore, the distance Ls1 (designated as an arrow dot line of the drawings) from the TSV 730 of the chip 700 to the cell array 722b is longer than the distance Lf1 (designated as an arrow full line of the drawings) from the TSV 730 to the cell array 722a. Thus, since a difference in access delay time exists due to the distance difference, cell data of the cell array 722a are accessed at a speed higher than cell data of the cell array 722b.

FIG. 22 is a view illustrating a layout of a second modified example in which a high-speed cell array and a low-speed cell array are constructed on each memory layer of the seventh example embodiment of FIG. 20. In the following description, the same elements as those of FIG. 20 will be assigned with the same reference numerals, and the detailed description will be omitted.

Referring to FIG. 22, according to the second modified example, a memory controller 712 is disposed on a logic layer 710. Cell arrays 720a of a memory layer 720, which are near a TSV 730 connected to the memory controller 712 on the logic layer 710, may be designated high-speed cell arrays, and cell arrays 720b of the memory layer 720, which are far away from the TSV 730 connected to the memory controller 712 on the logic layer 710, may be designated low-speed cell arrays. Likewise, cell arrays 722a of the memory layer 722, which are near the TSV 730, may be designated high-speed cell arrays, and cell arrays 722b of the memory layer 722, which are far away from the TSV 730, may be designated low-speed cell arrays.

Therefore, the distance Ls1 (designated as an arrow dot line of FIG. 22) from the memory controller 712 of the chip 700 to the cell array 722b is longer than the distance Lf1 (designated as an arrow full line of FIG. 21) from the memory controller 712 to the cell array 722a. Thus, since a difference in access delay time exists due to the distance difference, cell data of the cell array 722a are accessed at a speed higher than cell data of the cell array 722b.

Semiconductor memory devices described in example embodiments include high-speed access cell arrays and low-speed access cell arrays described in FIGS. 2 to 22.

FIG. 23 is a view illustrating a configuration of a DRAM device 800 according to an example embodiment.

The DRAM device of FIG. 23 may be, for example, a slow-fast DRAM (e.g., SFDRAM) including 8 memory banks.

Referring to FIG. 23, a cell array 802 includes a high-speed access cell array and a low-speed access cell array. A row decoder 808 drives a word line selected by decoding a row address. A sense amplifier 804 amplifies data read out on a bit line of the cell array 802. During a refresh, the sense amplifier 804 amplifies cell data read out on the bit line connected to a cell of the word line selected by a refresh address and writes the cell data on the cell. A column decoder 806 turns on a Y-switch selected by decoding a column address so that the selected bit line is connected to an IO line. A command decoder 818 receives a predetermined address signal, a chip selection signal /CS, a row address strobe signal /RAS, a column address strobe signal /CAS and a writable signal /WE, and decodes a command. A column address buffer and burst counter 814 generates addresses, the number of which corresponds to a burst length, starting from an input column address under the control of a control logic 820 receiving a control signal from the command decoder 818, and transfers the generated addresses to the column decoder 806. A mode register 810 receives an address signal and bank selection signals BA0, BA1 and BA2 and outputs the control signal to the control logic 820. The bank selection signals are used for selecting one from 8 banks.

A row address buffer of a row address buffer and refresh counter 812 receives an input row address and output the input row address to the row decoder 808. A refresh counter of the row address buffer and refresh counter 812 performs a count-up operation by receiving a refresh command and thus, transfers a count output as a refresh address.

The row address from the row address buffer and the refresh address from the refresh counter are provided to a multiplexer. During a refresh, the refresh address is selected and otherwise, the row address from the row address buffer is selected. Then, the selected address is provided to the row decoder 808.

A clock generator 826 receives external complementary clocks CK and /CK provided to the DRAM device and generates an internal clock when a clock enable signal CKE is logic HIGH. When the clock enable signal CKE is logic LOW, the supply of the internal clock from the clock generator 826 is interrupted.

A data control circuit 816 allows writing data and reading data to be input/output. A latch circuit 822 latches the writing data and reading data. An input/output buffer 824 allows data of a data terminal DQ to be input/output.

A high-speed access DLL 830 and a low-speed access DLL 832 generate a delayed, synchronized signal with respect to the external clocks CK and /CK and transfer the generated fast clock fastCK and slow clock slowCK to the input/output buffer 824, respectively.

The high-speed access DLL 830 generates a fast clock fastCK synchronized with the external clock by modeling a delay property corresponding to a data path Lf1 of the high-speed access cell array. The low-speed access DLL 832 generates a slow clock slowCK synchronized with the external clock by modeling a delay property corresponding to a data path Ls1 of the low-speed access cell array. A high-speed and low-speed access mode determination unit 828 determines whether an address ADDR corresponds to a predetermined high-speed and low-speed cell array by inputting the address ADDR. If the address corresponds to the high-speed cell array, the high-speed and low-speed access mode determination unit 828 outputs a control signal by which the high-speed access DLL 830 is activated. If the address corresponds to the low-speed cell array, the high-speed and low-speed access mode determination unit 828 outputs a control signal by which the low-speed access DLL 832 is activated.

The data read out from the memory cell array 802 are transferred from the latch circuit 822 to the input/output buffer 824. The input/output buffer 824 outputs the reading data from the data terminal DQ at a double data rate using rising and falling edges of the clock signal synchronized with the external clock CK by the low-speed access DLL 832.

DM is a data mask signal for the write data and written when the data mask signal is logic HIGH. DQS and /DQS are differential data strobe signals to define timings of a data write and a data read. They are I/O signals which are an input signal during writing and an output signal during reading. TDQS and /TDQS are differential signals for providing compatibility of X8 data configuration with X4 data configuration. ODT (On-DieTermination) is a control signal for turning on or off longitudinal resistances of DQ, DQS, /DQS, TDQS and /TDQS.

Although a conventional example of an SFDRAM device is schematically depicted in FIG. 23, the conventional example is applicable to various types of devices having various configurations and is not intended to limit the scope of example embodiments.

FIG. 24 is a block diagram illustrating an electronic system including a semiconductor memory device according to an example embodiment. Referring to FIG. 24, the electronic system 900 includes an input device 910, an output device 920, a processor device 930 and a semiconductor memory device 800. The processor device 930 may control the input device 910, the output device 920, the processor device 930 and the semiconductor memory device 800 through each corresponding interface. The processor device 930 may include at least one of at least one microprocessor, a digital signal processor, a microcontroller and logic devices capable of performing functions similar to those of the microprocessor, the digital signal processor and the microcontroller. Each of the input and output devices 910 and 920 may include at least one selected from a keypad, a keyboard and a display device.

The semiconductor memory device 800 includes, for example, an SFDRAM (Slow-Fast DRAM) having two access times by intentionally dividing cell arrays into a high-speed cell array and a low-speed cell array according to a physical distance with respect to an input/output pad in one chip. The semiconductor memory device 800 includes a low-speed access cell array placed physically away from a data input/output DQ pad and a high-speed access cell array placed physically near the data input/output DQ pad. A distance between a cell of the low-speed access cell array 110 and the data input/output DQ pad is equal to Ls1 (a length between a pad and an I/O sense amplifier)+Ls2 (a length between a bit-line sense amplifier and a cell). A distance between a cell of the high-speed access cell array and the data input/output DQ pad is equal to Lf1 (a length between a pad and an input/output sense amplifier)+Lf2 (a length between a bit-line sense amplifier and a cell). Thus, difference in the access delay time may exist due to Ls1+Ls2>Lf1+Lf2.

FIG. 25 shows a computer system including a semiconductor memory device according to an example embodiment. Referring to FIG. 9, a computer system 950 may include a central processing unit 954 electrically connected to a system bus 952, a user interface 956, a memory 800 and a modem 958 such as a baseband chipset. The user interface 956 may be an interface for transmitting data to a communication network and receiving data from the communication network. The user interface 956 may be in a wire or wireless type and may include an antenna or a wire/wireless transceiver. The data which are provided through the user interface 956 or the modem 958 or processed by the central processing unit 954 may be stored in the memory 800.

The memory 800 includes, for example, an SFDRAM (Slow-Fast DRAM) having two access times by intentionally dividing cell arrays into a high-speed cell array and a low-speed cell array according to a physical distance with respect to an input/output DQ pad in one chip. The semiconductor memory device 800 includes a low-speed access cell array placed physically away from a data input/output DQ pad and a high-speed access cell array placed physically near the data input/output DQ pad. A distance between a cell of the low-speed access cell array and the data input/output DQ pad is equal to (Ls1 (a length between a data input/output DQ pad and an I/O sense amplifier)+Ls2 (a length between a bit-line sense amplifier and a cell)). A distance between a cell of the high-speed access cell array and the data input/output DQ pad is equal to Lf1 (a length between a data input/output DQ pad and an input/output sense amplifier)+Lf2 (a length between a bit-line sense amplifier and a cell). Thus, difference in the access delay time may exist due to Ls1+Ls2>Lf1+Lf2.

When the computer system 950 according to an example embodiment is a mobile device, a battery may be further provided for supplying an operation voltage of the computer system 950. Although not depicted in the drawings, an application chipset, a CIP (Camera Image Processor) and an input/output device may be further provided to the computer system 950.

When the computer system 950 according to an example embodiment is an equipment of performing wireless communication, the computer system 950 may be used in a communication system, for example, such as CDMA (Code Division Multiple Access), GSM (Global System for Mobile communication), NADC (North American Multiple Access) or CDMA2000, an NFC (Near Field Communication) communication apparatus, or a WiFi communication module.

The foregoing is illustrative of the present disclosure and is not to be construed as limiting thereof. Although a few example embodiments have been described, those skilled in the art will readily appreciate that many modifications are possible in the example embodiments without materially departing from the novel teachings and advantages of the present disclosure. Accordingly, all such modifications are intended to be included within the scope of the present disclosure as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor memory device, comprising:
a plurality of data input/output DQ pads disposed on a semiconductor substrate; and
a plurality of first and second memory cell arrays disposed on the semiconductor substrate,
wherein each path of a first set of data paths from each of the plurality of first memory cell arrays to a corresponding DQ pad is physically shorter than each path of a second set of data paths from each of the plurality of second memory cell arrays to the corresponding DQ pad,
wherein each of the plurality of first memory cell arrays is a designated high-speed access cell array,
wherein each of the plurality of second memory cell arrays is a designated low-speed access cell array, and
wherein a size of the each of the plurality of first memory cell arrays is smaller than a size of the each of the plurality of second memory cell arrays.

2. The semiconductor memory device of claim 1, further comprising:
a plurality of command and address CMD/ADDR pads disposed on the semiconductor substrate,
wherein the DQ and CMD/ADDR pads are disposed along one of a horizontal central line and a vertical central line of the semiconductor substrate.

3. The semiconductor memory device of claim 2, wherein the CMD/ADDR pads are disposed at the horizontal central line and the DQ pads are disposed at left and right sides of the CMD/ADDR pads.

4. The semiconductor memory device of claim 2, wherein the CMD/ADDR pads are disposed at a center of the vertical central line and the DQ pads are disposed at upper and bottom sides of the CMD/ADDR pads.

5. The semiconductor memory device of claim 2, wherein the DQ pads are disposed along one of left and right vertical edge lines, and the CMD/ADDR pads are disposed along a remaining one of the left and right vertical edge lines.

6. The semiconductor memory device of claim 2, wherein the DQ pads are disposed along one of left and right vertical edge lines, and the CMD/ADDR pads are disposed along a vertical line of the semiconductor substrate.

7. The semiconductor memory device of claim 1, further comprising:
a plurality of command and address CMD/ADDR pads disposed on the semiconductor substrate,
wherein the DQ pads are disposed at a center of a vertical central line of the semiconductor substrate and the CMD/ADDR pads are disposed along a horizontal central line of the semiconductor substrate.

8. The semiconductor memory device of claim 1, further comprising:
a plurality of command and address CMD/ADDR pads disposed on the semiconductor substrate,
wherein the DQ pads are disposed along one of left and right vertical edge lines of the semiconductor substrate, and the CMD/ADDR pads are disposed along one of upper and lower horizontal edge lines of the semiconductor substrate.

9. The semiconductor memory device of claim 8, wherein one of the plurality of first memory cell arrays and one the plurality of second memory cell arrays adjacent to each other share an input/output sense amplifier circuit.

10. The semiconductor memory device of claim 8, wherein one of the plurality of first memory cell arrays and one of the plurality of second memory cell arrays adjacent to each other have individual input/output sense amplifier circuits, respectively.

11. A semiconductor memory device, comprising:
a logic layer;
a first memory layer located above the logic layer, the first memory layer including a plurality of first and second memory cell arrays and a first set of data input/output DQ pads disposed on a substrate of the first memory layer;
a second memory layer located above the first memory layer, the second memory layer including a plurality of third and fourth memory cell arrays and a second set of data input/output DQ pads disposed on a substrate of the second memory layer; and
a vertical connection member configured to electrically connect the logic layer, the first memory layer, the second memory layer to each other, the vertical connection member being a data path between the logic layer and each of the first and second memory layers,
wherein for the first memory layer, a shortest data path from one of the plurality of first memory cell arrays to a first DQ pad of the first set of DQ pads is physically shorter than a shortest data path from one of the plurality of second memory cell arrays to the first DQ pad,
wherein for the second memory layer, a shortest data path from one of the plurality of third memory cell arrays to a second DQ pad of the second set of DQ pads is physically shorter than a shortest data path from one of the plurality of fourth memory cell arrays to the second DQ, and
wherein each of the plurality of first and third memory cell arrays is a designated high-speed access cell array and each of the plurality of second and fourth memory cell arrays is a designated low-speed access cell array.

12. The semiconductor memory device of claim 11, wherein the first set of DQ pads are disposed along a first direction of the substrate of first memory layer and are electrically connected to the vertical connection member, and
wherein the second set of DQ pads are disposed along a first direction of the substrate of second memory layer and are electrically connected to the vertical connection member.

13. The semiconductor memory device of claim 12, wherein each of the first and second memory layers includes a plurality of ADDR/CMD pads disposed along a second direction perpendicular to the first direction.

14. A semiconductor memory device, comprising:
a substrate extending a first direction and a second direction perpendicular to the first direction;
a first set of memory cell arrays disposed on the substrate, each array of the first set of memory cell arrays designated as a high-speed access cell array;
a second set of memory cell arrays disposed on the substrate, each array of the second set of memory cell arrays designated as a low-speed access cell array; and
a plurality of pads disposed on the substrate and including data input/output DQ pads and address and command ADDR/CMD pads,
wherein the DQ pads are disposed along the first direction of the substrate, and
wherein for each memory cell array of the first set of memory cell arrays, a shortest data path from the memory cell array to a corresponding DQ pad is physically shorter than any shortest data path from anyone of the second set of memory cell arrays to the corresponding DQ pad.

15. The semiconductor memory device of claim 14, further comprising:
a first set of input/output sense amplifiers electrically coupled to the first set of memory cell arrays, and configured to amplify data read from the first set of memory cell arrays; and
a second set of input/output sense amplifiers electrically coupled to only the second set of memory cell arrays, and configured to amplify data read from the second set of memory cell arrays,
wherein a data path extends from each of the first set of input/output sense amplifiers to the corresponding DQ pad, and
wherein a data path extends from each of the second set of input/output sense amplifiers to the corresponding DQ pad.

16. A memory system comprising:
a logic layer including a memory controller;
first and second memory layers each memory layer including the semiconductor memory device of claim 14, each of the first and second memory layers configured to be controlled by the memory controller; and
a vertical connection member configured to electrically connect the logic layer, the first memory layer and the second memory layer,
wherein for each memory cell array of the first set of memory cell arrays, a shortest data path from the memory cell array to the vertical connection member is shorter than any shortest data path from anyone of the second set of memory cell arrays to the vertical connection member.

17. A memory system comprising:
a logic layer including a memory controller;
first and second memory layers each memory layer including the semiconductor memory device of claim 14, each of the first and second memory layers configured to be controlled by the memory controller; and
a vertical connection member configured to electrically connect the logic layer with the at least one memory layer,
wherein for each memory cell array of the first set of memory cell arrays, a shortest data path from the memory cell array to the logic layer is shorter than any shortest data path from anyone of the second set of memory cell arrays to the logic layer.

18. The semiconductor memory device of claim 14, wherein the ADDR/CMD pads are disposed along the first direction and between the DQ pads.

19. The semiconductor memory device of claim 14, wherein the ADDR/CMD pads are disposed along the first direction, and
wherein the DQ pads are disposed between the ADDR/CMD pads.

20. The semiconductor memory device of claim 14, wherein the ADDR/CMD pads are disposed along the second direction, and
wherein the DQ pads are disposed between the ADDR/CMD pads.
